(19) United States
(12) Patent Application Publication
(10) Pub. No.: US 2007/0184687 A1
(43) Pub. Date: Aug. 9, 2007

(54) Circuit board provided with digging depth detection structure and transmission device with the same mounted

(76) Inventors: Hisaaki Kanai, Yokohama (JP); Norio Chujo, Tokyo (JP); Masayoshi Yagyu, Hannou (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/657,462

(22) Filed: Jan. 25, 2007

(30) Foreign Application Priority Data
Jan. 26, 2006 (JP) 2006-017047

(51) Int. Cl. H05K 1/00

(52) U.S. Cl. 439/79

(57) ABSTRACT

One of a group which is located on the side of a main surface of the circuit board than the one conductive layer of the plurality of conductive layers is used as a terminal to detect the digging depth of the through hole, and the digging of the through hole is stopped according to the change of the conductive state between the detection terminal and the through hole (or the one conductive layer which is electrically connected to this). A circuit board is formed so that the detection terminal in a group of the plurality of conductive layers contacts with the drill which dig the through hole and a group of the conductive layers except the detection terminal does not contact with the drill, respectively.

### BACKGROUND OF THE INVENTION

The present invention relates to a circuit board (a printed circuit, a laminated circuit board) which is formed laminating a plurality of conductive layers, and in particular, to detection structure (check structure) of the digging depth which is appropriate for improving the precision of the digging of the circuit board with a zaguri processing (Counterboring), etc. with low cost, a digging technique (zaguri processing technique) of a stub in a through hole in a printed circuit, and a printed circuit which is appropriate for the fast speed signal transmission in the GHz (Giga Hertz) band which is realized applying these techniques, and a device which is configured using the same such as a communication equipment, a server, a router, etc.

Recently, the data transfer capacity between the ICs or between the transmission devices has been rapidly increasing, and with this, the data transmission rate per one transmission route which electrically connects a driver circuit and a receiver circuit configuring the IC or the transmission device has been becoming fast speed such as, for example, 2.5 G bits (gigabits)/second or 10 G bits/second.

On the other hand, when one of the conductive layers of the circuit board which is formed laminating a plurality of conductive layers via a dielectric material (a dielectric layer) (hereinafter it will be described as a printed circuit board) is used for the above-mentioned data transmission, in order to achieve the impedance matching of the conductive layer (a transmission route), a conductor called a stub which extends from this conductive layer in the direction of laminated layers of the printed circuit board is formed. The stub forms a capacitor or an inductor for the conductive layer (the transmission route) with an electrical length of this stub which is determined by the product of the extension length from the conductive layer and the phase constant which is determined by the wave length of the data signal transmitted by this conductive layer. The data transmission by the printed circuit board can be performed through the conductive layers of different lying levels which are connected by a through hole extending in its direction of laminated layers. Thus, in the printed circuit board, the impedance of the transmission route in which the lying layers of the signal wiring differ is matched, for example, by a stub (a stub of a through hole) which is formed further extending a through hole connecting two lying layers.

In accordance with that the data transmission by the conductive layer of the printed circuit board becomes faster as described above, the distortion of its signal wave form by the above-mentioned stub of the through hole becomes likely to occur. In particular, when the electrical length of the above-mentioned stub becomes equal to or greater than 1/10 of the electrical length of 1 bit of the data transmission signal, the distortion of its signal wave form becomes remarkable and the absence of the data in the transmission route and the malfunction of the communication equipment, the server, and the router, etc. caused by this often occur. As a means to solve such a problem, there is a processing technique to improve the distortion of the signal wave form by the stub by removing a part of the through hole which is to be the stub (for example, a redundant portion) by a digging by a drill. This processing technique conventionally set the digging depth of the stub so that the stub after the digging by the drill is to have the length with which the stub would not cause the above-mentioned absence of the data or the malfunction of the device with the length of the stub of the through hole which is estimated from the thickness of the design of the printed circuit board as a standard. The techniques to adjust the length of the stub formed in the circuit board such as a printed circuit board, etc. by the digging by the drill are disclosed, for example, in a patent reference 1 (JP-A-10-135647 gazette), a patent reference 2 (JP-A-8-323697 gazette), and a patent reference 3 (JP-A-5-4105 gazette).

### SUMMARY OF THE INVENTION

However, with the above-mentioned method for adjusting the stub length by setting the digging length, it is sometimes seen that the stub which is left after the digging still remains longer than the desired length because of the manufacturing tolerance of the thickness of the printed circuit board or the variation in the digging depth. Therefore, the signal wave form which is transmitted by the printed circuit board is not improved as intended and sometime the absence of the data or the malfunction of the device occurs because of its distortion.

The present invention provides printed circuit board structure which is not likely to suffer the distortion of the precision of the digging processing by the manufacturing tolerance of the thickness of the printed circuit board or the variation in the digging depth which is described above as a problem of the prior art, and a digging depth adjusting method.

The printed circuit board structure of the present invention is characterized in that it is provided with a digging depth check terminal which changes its conductive state with a signal wiring when the stub reaches the desired length when digging the stub of the through hole.

The new circuit board (the structure to check its digging depth) provided by the present invention will be illustrated as below.

Structure 1. A circuit board provided with a signal wiring to transmit signals, conductive layers which are connected to a power supply or ground, a dielectric material to laminate the signal wiring and the conductive layers, and a through hole which extends in a direction of laminated layers of the signal wiring and the conductive layers and is to change a lying position of the signal wiring in the direction of laminated layers, wherein a digging depth check terminal which changes its conductive state with the through hole when the through hole reaches a desired length by being dug is provided. This structure will be reflected in a printed circuit board (a printed circuit with digging depth controllable) which will be described later referring to FIG. 1 and FIG. 3.

Structure 2. The structure 1 wherein an insulating space is provided between the digging depth check terminal and the through hole, and a radius of an area consisting of an outer conductor formed in the through hole and the insulating space surrounding the same is smaller than a digging radius of the through hole. This structure will be reflected in a printed circuit board (digging depth check terminal structure) which will be described later referring to FIG. 4.

Structure 3. The structure 1 wherein the digging depth check terminals are provided in the plurality of through holes respectively, and the plurality of digging depth check terminals are electrically connected to each other. This structure will be reflected in a printed circuit board (digging depth check terminal structure) which will be described later referring to FIG. 5.

Structure 4. A circuit board comprising the structure 1 wherein the through hole is partly dug from a main surface of the circuit board toward the direction of laminated layers, and a digging of the through hole is stopped at the time point when the conductive state between this through hole and the digging depth check terminal changes. The main surface of the circuit board crosses the direction of laminated layers. This structure will be reflected in a printed circuit board (with its through hole dug) which will be described later referring to FIG. 2.

Structure 5. A circuit board provided with a signal wiring to transmit signals, a plurality of conductive layers which are connected to a power supply or ground respectively, a dielectric material to laminate the signal wiring and the plurality of conductive layers alienating them each other, and a through hole which extends in a direction in which the signal wiring and the plurality of conductive layers are laminated and changes a lying position of the signal wiring in the direction of laminated layers, wherein between each of the plurality of conductive layers and the through hole a clearance which secures the isolation between each conductive layer and the through hole is provided respectively on a lying level of each conductive layer, and a form of the clearance provided in one of the plurality of conductive layers is different from forms of the clearances provided in the others of the plurality of conductive layers. This structure will be reflected in a printed circuit board (a printed circuit with digging depth controllable) which will be described later referring to FIG. 6.

Structure 6. The structure 5 wherein a diameter of the clearance provided in the one conductive layer is smaller than a diameter of a drill to dig the through hole, and diameters of the clearances provided in the other conductive layers are bigger than the diameter of the drill. This structure also will be reflected in a printed circuit board (a printed circuit with digging depth controllable) which will be described later referring to FIG. 6.

Structure 7. A circuit board comprising the structure 5 or the structure 6 wherein the through hole is partly dug from a main surface of the circuit board toward the direction of laminated layers, and the digging of the through hole is stopped at the time point when the conductive state between this through hole and the one of the plurality of conductive layers changes. The main surface of the circuit board crosses the direction of laminated layers. This structure will be described later in an embodiment 5.

Structure 8. A printed circuit board provided with a through hole received a digging processing wherein a conductor which is isolated from the through hole is exposed in a digging level of the through hole. This structure will be described in detail as the following in a circuit board which is formed laminating a plurality of conductive layers (a printed circuit board). A circuit board provided with a plurality of conductive layers laminated in a first direction, a dielectric material which spaces the plurality of conductive layers each other, and a through hole which extends and exists in the first direction and electrically connects a pair of the plurality of conductive layers, wherein the through hole is terminated with a digging aperture formed by digging the circuit board from one of main surfaces crossing the first direction in the first direction, an inside wall of the digging aperture which extends and exists in the first direction consists of the dielectric material, and one of the plurality of conductive layers other than the pair thereof is exposed from the inside wall of the digging aperture. This structure will be described later in an embodiment 1, an embodiment 2, and the embodiment 5. Now, the above-mentioned first direction indicates the direction of the laminated layers of the plurality of conductive layers forming the circuit board. Also, the digging aperture extends and exits in the first direction.

Structure 9. A transmission device which has a circuit board comprising the structure 4 or the structure 7 mounted, wherein the through hole provided in the circuit board is dug to a desired depth by a method for controlling the digging depth of the circuit board according to the present invention.

These and other objects, features and advantages of the invention will be apparent from the following more particular description of preferred embodiments of the invention, as illustrated in the accompanying drawings.

### BRIEF DESCRIPTION OF THE DRAWINGS

FIG. 1 is a cross section diagram showing enlarged structure which can monitor its digging depth by a conductive state between a signal wiring and a digging depth check terminal in a printed circuit board according to an embodiment 1 of the present invention.

FIG. 2A-2C are explanatory diagrams of a method for adjusting the digging depth when digging a stub (a part of a through hole) provided in the printed circuit board of the embodiment 1 with a conductive drill.

FIG. 3 is a cross section diagram showing enlarged structure which stops its digging by detecting a change of the conductivity between the signal wiring and the digging depth check terminal in a printed circuit board according to an embodiment 2 of the present invention.

FIG. 4 is a plan view showing a pattern (an inside level form) of the digging depth check terminal in. one of the lying levels of a printed circuit board which will be explained in an embodiment 3 of the present invention.

FIG. 5 is a plan view showing an inside level form of the digging depth check terminal provided corresponding to each of the plurality of through holes in one of the lying levels of a printed circuit board which will be explained in an embodiment 4 of the present invention.

FIG. 6 is a cross section diagram showing enlarged structure for which one of the conductors which connect to a power supply or ground is used as its digging depth check terminal in a printed circuit board according to an embodiment 5 of the present invention.

FIG. 7 is an explanatory diagram regarding a device which receives and transmits fast speed signals and mounts the printed circuit board as an application example of the same of the present invention.

### DESCRIPTION OF THE EMBODIMENTS

The structure of a circuit board according to the present invention (hereinafter it will be described as a printed circuit board) and a method for adjusting its digging depth will be explained below referring to the figures.

### Embodiment 1

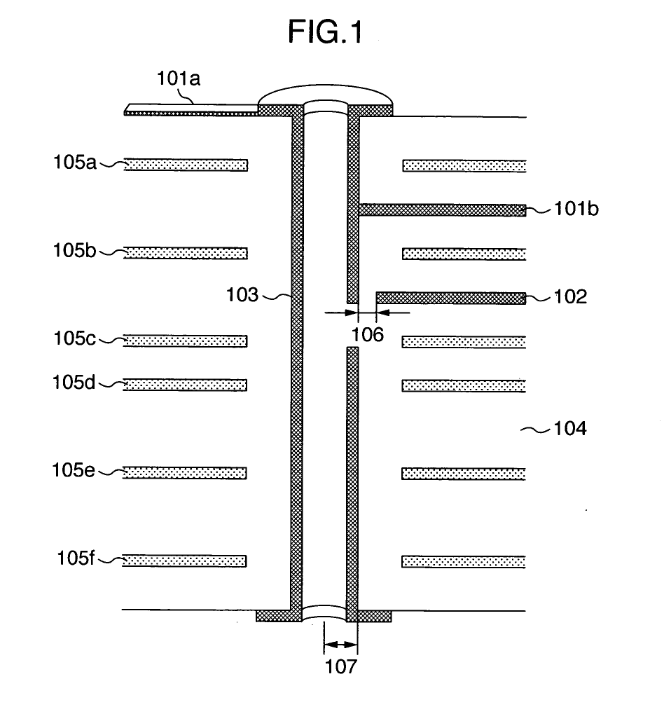

FIG. 1 shows an embodiment of the structure of the printed circuit board according to the present invention which is provided with a signal wiring and a digging depth check terminal and can detect the depth of the digging which will be performed thereon by monitoring a change of its conductive state. As described before, the printed circuit board (the circuit board) shown in FIG. 1 is provided with a plurality of conductive layers laminated via a dielectric material (dielectric layer) and at least one of the conductive layers is used for the transmission of a data signal, etc. These conductive layers are formed on each of the planes crossing the direction of laminated layers respectively, and the form on the plane is appropriately patterned according to the use of the conductive layer. Not only in this embodiment but also in the explanation of the printed circuit board which will be described below, these conductive layers will be described as a signal wiring or a digging depth check terminal according to its use but these conductive layers may be formed with the same conductive material or the same patterning method.

The printed circuit board of this embodiment is provided with signal wirings to transmit signals 101a, 101b, conductive layers 105a-105f connected to a power supply or ground, a dielectric material 104 to laminate the conductive layers, a through hole 103 to electrically connect the signal wirings 101a,101b, and a digging depth check terminal 102 to monitor the digging depth. The dielectric material 104 in which the signal wiring 101b, the digging depth check terminal 102, and the conductive layers 105a-105f are buried is formed by, for example, ceramics or resin (for example, an adhesive material) and a plurality of rigid layers which are laminated via this material. The rigid material layer is configured with glass epoxy, etc. The signal wirings 101a, 101b, the digging depth check terminal 102, and the patterns of the conductive material shown as the conductive layers 105a-105f are formed respectively on a plurality of “stages, levels” which form the laminated layers structure of the printed circuit board. In this specification the plurality of “stages” are described as “lying levels” of the patterns of the conductive material, and the pattern (including a solid pattern) of the conductive material which is formed thereon is also described as a lying layer. A pair of lying levels which are adjacent to each other is spaced via the dielectric material 104 and the patterns of the conductive material (the lying layers) which are formed respectively on the pair of the lying levels are electrically insolated by the dielectric material 104. In the printed circuit board which is provided with the dielectric material 104 which is formed by the plurality of rigid layers and the resign which sticks together a pair of adjacent ones, a pair of lying layers adjacent in the direction of laminated layers (for example, the signal wiring 101b and the conductive layer 105b) are formed respectively on the opposite main surfaces of one of the rigid layers, and the other pair of the adjacent lying layers (for example, the conductive layer 105c and the digging depth check terminal 102) are formed respectively on the main surfaces of a pair of the rigid layers opposing via the resin.

When the upper surface of the printed circuit board shown in FIG. 1 is defined as a “first main surface of the printed circuit board” and its lower surface is defined as a “second main surface of the printed circuit board”, the through hole 103 pierces the printed circuit board from the first main surface on which the signal wiring 101a is formed toward the second main surface in the direction of laminated layers. A film of the conductive material is formed on an inside wall of the through hole 103, around its aperture on the first main surface, and around its aperture on the second main surface, and a part of the conductive material film surrounding the aperture of the through hole 103 on the first main surface is connected to the signal wiring 101a. The conductive material film formed on the inside wall of the through hole 103 will be hereinafter also described as an “outer conductor”. The conductive structure in the inside of the through hole 103 is not limited to the “outer conductor” shown in FIG. 1, but may be formed to fill the inside of the through hole 103 with the conductive material. The through hole 103 shown in FIG. 1 electrically connects the signal wiring 101a formed on the first main surface of the printed circuit board and the signal wiring 101b formed in the second lying level counting from the first main surface by the above-mentioned conductive material film (including the outer conductor) formed thereon. An extended part of the through hole 103 which extends from the second lying level to the second main surface of the printed circuit board serves as a stub which determines the impedance of the transmission route which is formed connecting the signal wiring 101a and the signal wiring 101b.

The stub of the through hole 103 shown in FIG. 1 has a “stub length” which extends from the lying level on which the signal wiring 101b is formed reaching to the second main surface of the printed circuit board crossing 6 layers of lying levels (but without electrically connecting to each of them) on which the conductive layers 105b-105f and the digging depth check terminal 102 are formed respectively. However, when the “stub length” is redundant to match the impedance of the transmission route according to the frequency of the signal to be transmitted by the transmission route which is formed by the signal wiring 101a and the signal wiring 101b, the drill is applied to the aperture of the through hole 103 on the second main surface of the printed circuit board, and the through hole 103 is dug toward the first main surface of the printed circuit board. By making the digging radius (or the drill radius) by the drill greater than the radius 107 of the through hole 103 (the outer periphery of the outer conductor), the outer conductor forming the stub of the through hole 103 is removed according to the length which has been dug (the depth from the second main surface). As a result, the outer conductor which forms the stub of the through hole 103 is terminated without reaching to the second main surface although it extends with a predetermined length from the lying level on which the signal wiring 101b is formed toward the second main surface of the printed circuit board. This “predetermined length” will be hereinafter described as a “residual stub length”.

The digging depth check terminal 102 according to the present invention is formed on the other lying level which is spaced with the distance shorter than the desired residual stub length from the lying level on which the signal wiring 101b is formed on the side of the second main surface (the lower surface) of the printed circuit board. The digging depth check terminal 102 is formed on the lying layer alternated along the direction of laminated layers of the printed circuit board and is provided in close vicinity to one of the pair of the signal wirings 101a, 101b (the signal siring 101b) which is electrically connected by the through hole 103. The function of the stub for the transmission route changes with its critical length (which depends on the wave length of the signal transmitted by the transmission route) as a boundary. When the desired residual stub length is set to be this critical value or a value close to this, if the length of the stub of the through hole 103 which is left after the digging is greater than the desired residual stub length, in the same way as the stub before the digging shown in FIG. 1, the impedance matching of the transmission route becomes insufficient. However, if the length of the stub of the through hole 103 which is left after the digging is equal to or shorter than the desired residual stub length, the impedance of the transmission route is sufficiently matched. Taking this in consideration, the lying position of the digging depth check terminal 102 is defined as described above. It is a matter of course, but the lying layer which the digging depth check terminal 102 forms is selected or its position is determined so that the digging by the drill removes the stub of the through hole 103 reaching the lying level on which the signal wiring 101b is formed or so that the digging would not shave the outer conductor of the through hole 103 electrically connecting the signal wiring 101a and the signal wiring 101b exceeding this lying level. For example, it is recommendable to locate at least one layer of the lying level on which the other pattern of the conductive material (for example, the conductive layer 105b) is formed between the signal wiring 101b and the digging depth check terminal 102.

Between the lying level of the digging depth check terminal 102 and the through hole 103 (the outer conductor) an insulating space 106 is provided, thereby the outer conductor of the through hole 103 before the digging and the digging depth check terminal 102 are electrically isolated. Also, if the sum of the insulating space 106 and the radius 107 of the outer conductor of the through hole 103 is made to be smaller than the radius of the digging drill, when the digging of the through hole 103 reaches the lying level of the digging depth check terminal 102, the outer conductor of the through hole 103 and the digging depth check terminal 102 are electrically connected by the digging drill. As a digging drill it is recommendable to use the kind of equipment which is provided with an edge made of the conductive material such as metal or alloy, etc., but the kind of equipment which is provided with an edge which is formed scattering the conductive material on the basic material such as ceramics, etc. or covering the surface of the basic material with the conductive material may be used.

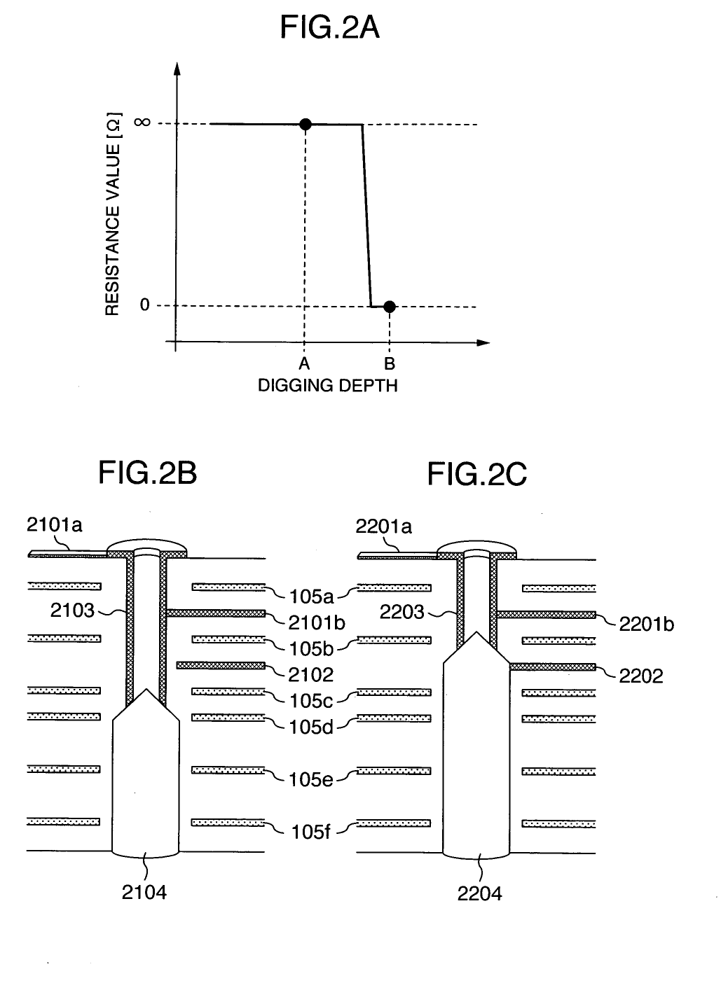

FIGS. 2A-2C show a method for adjusting the digging depth in the step of digging the stub formed in the printed circuit board shown in FIG. 1 (the stub of the through hole 103) with a conductive drill. FIG. 2A is a graph showing the relation between the digging depth and the direct current resistance value between the signal wiring and the digging depth check terminal, and the horizontal axis indicates the digging depth and the vertical axis indicates the resistance value.

FIG. 2B shows cross section structure of the printed circuit board with a through hole 2103 (corresponding to the through hole 103 of FIG. 1) dug with the digging depth A shown in FIG. 2A. In FIG. 2B, as the conductive digging drill (the drill edge exhibiting the conductivity) 2104 has not reached a digging depth check terminal 2102 (corresponding to the digging depth check terminal 102 of FIG. 1) a signal wiring 2101b (corresponding to the signal wiring 101b of FIG. 1) and the digging depth check terminal 2102 are electrically isolated. The stub of the through hole 2103 extending from the signal wiring 2101b toward the lower surface (the second main surface) of the printed circuit board reaches the lying level of the fourth layer (on which the conductive layer 105d of FIG. 1 is formed) counting from the lying level on which the signal wiring 2101b is formed, and its residual stub length is longer than the distance which separates the digging depth check terminal 2102 and the signal wiring 2101b which is close to this in the direction of laminated layers of the printed circuit board.

FIG. 2C shows cross section structure of the printed circuit board with a through hole 2203 (corresponding to the through hole 103 of FIG. 1) dug with the digging depth B shown in FIG. 2A. As the conductive digging drill (the drill edge exhibiting the conductivity) 2204 has reached a digging depth check terminal 2202 (corresponding to the digging depth check terminal 102 of FIG. 1) a signal wiring 2201b (corresponding to the signal wiring 101b of FIG. 1) and the digging depth check terminal 2202 are electrically conducted via the digging drill 2204. The stub of the through hole 2203 extending from the signal wiring 2201b toward the second main surface of the printed circuit board does not reach the lying level of the second layer (the digging depth check terminal 2202 is formed) counting from the lying level on which the signal wiring 2201b is formed, and its residual stub length is shorter than the distance which separates the digging depth check terminal 2202 and the signal wiring 2201b which is close to this in the direction of laminated layers of the printed circuit board.

As described above, by performing the digging processing of the stub (the partial removing of the outer conductor) monitoring the conductive state between the signal wiring and the digging depth check terminal and stopping the digging processing at the time point in which the conductive state changed, it becomes possible to dig the stub to the depth in which it has the desired residual stub length with high precision. Here, in this embodiment it has been shown an example of the laminated layers configuration of the patterns of the conductive material in the printed circuit board, the effect and the industrial advantage of the present invention are not limited to this laminated layers configuration and can be obtained with the printed circuit board (the circuit board) comprising the other laminated layers configuration.

Although the above explanation referring to FIG. 2B and FIG. 2C is described as the example in which the through hole 103 of the printed circuit board shown in FIG. 1 is dug, the different reference numbers are assigned respectively to the main configuration elements shown in each figure. The intention is to give the impression that FIG. 2B and FIG. 2C show the cross section of a “product (a printed circuit board)” obtained by performing the digging processing on the printed circuit board of FIG. 1, namely a “product” different from the printed circuit board before the digging processing. For example, the through holes 103, 2103, 2203 have the lengths of the stubs formed on each of them which differ from each other. Therefore, the impedances of the transmission routes which are formed by the pairs of the signal wirings (101a+101b, 2101a+2101b, 2201a+2201b) connected by the through holes 103, 2103, 2203 of each of them differ from each other.

In FIG. 2B and FIG. 2C, the reference numbers 2104, 2204 which denote the digging drill also denote inside walls of the “apertures” which is dug by this drill. This aperture is formed with a caliber greater than the through holes 2103, 2203, and the inside wall thereof is formed by the dielectric material 104. This inside wall of the aperture will be hereinafter described as a digging processed surface after the digging processing (or simply a digging processed surface). The ones of the plurality of conductive material layers which form the printed circuit board other than the signal wiring which is connected by the through hole (hereinafter they will be described as the conductive layers 105a-105f) are alienated from the through hole at their lying levels. Also, in order to avoid that during the digging step of the through hole by the drill the fragments (the chips) brought from one of the conductive layers 105a-105f would contacts with the other one and the electrical short-circuit would occur between them, some of the conductive layers 105a-105f which are formed at least on the lying levels which cross the stub of the through hole (the conductive layers 105b-105f) are separated from the area which can be dug on the lying level. In the printed circuit board thus configured the digging depth check terminal 2202 shown in FIG. 2C is inevitably exposed from the digging processed surface which consists of the dielectric material 104. Also, although the digging depth check terminal 2102 of FIG. 2B is not exposed from the digging processed surface it reaches close to the outer conductor of the through hole 2103 on its lying level as compared with the conductive layers 105b-105f. In other words, in the printed circuit board shown in FIG. 2C the characteristic that the conductor other than the through hole is exposed from the digging processed surface is shown. This is also one of the characteristics of the printed circuit board according to the present invention.

The signal wirings 101b, 2101b, 2201b, the digging depth check terminals 102, 2102, 2202, and the conductive layers 105a-105f shown in FIG. 1, FIG. 2B, and FIG. 2C may be electrically connected to the terminal which is formed on either one of or both of the upper surface (the first main surface) and the lower surface (the second main surface) of the printed circuit board or to the other conductive layer through the other through hole which is not shown in any of the figures. Also, a group of conductive layers 105a-105f with the same use (which is set to the reference potential or the power supply potential) may be electrically connected in the direction of laminated layers of the printed circuit board by the other through hole which is not shown in any of FIG. 1, FIG. 2B, and FIG. 2C (for example, the one that does not extend and exist to the first main surface or the second main surface of the printed circuit board).

As described above, by performing the digging processing of the stub which is provided in the printed circuit board using the digging depth check terminal which previously has been formed in this printed circuit, the variation in the residual stub length caused by the manufacturing tolerance of the thickness of the printed circuit board itself or the variation in the depth of the digging by the drill is reduced and the impedance of the signal transmission route which is formed on the printed circuit board is matched with high precision and repeatability. As a result, the wave form of the signal which is transmitted by the transmission route of the printed circuit board is maintained in the desired state.

### Embodiment 2

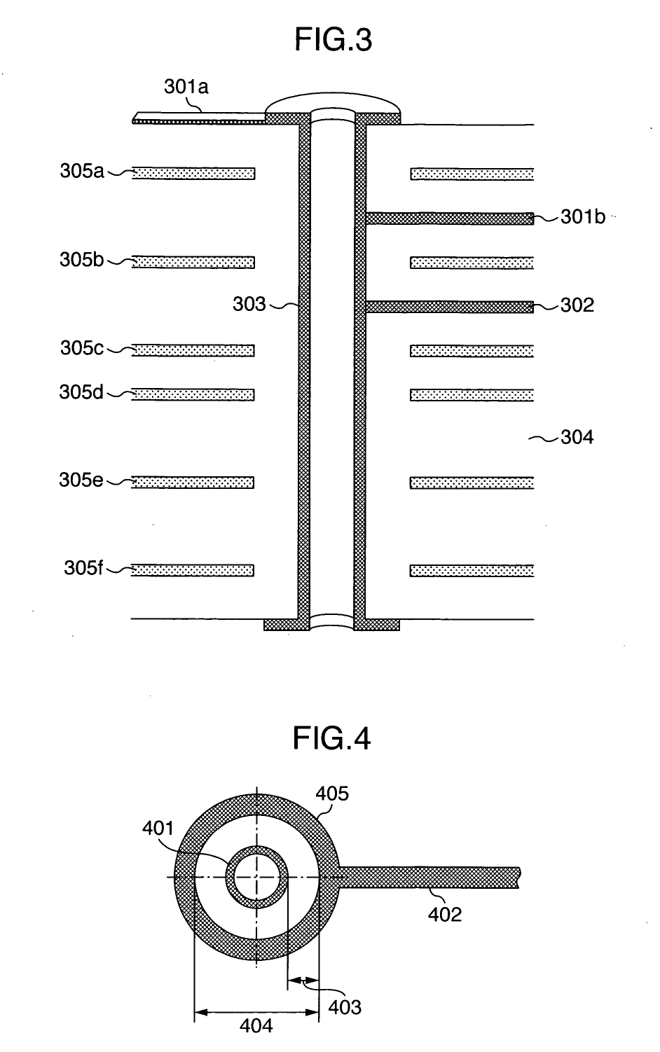

FIG. 3 is a cross section diagram showing an embodiment of the printed circuit board according to the present invention which is appropriate to dig a through hole 303 in the printed circuit board with a drill which has an edge formed by a non-conductive material such as ceramics, etc. (a non-conductive drill). The through hole 303 of the printed circuit board shown in FIG. 3 exhibits the form before being dug by the drill in the same ways as FIG. 1 and pierces the printed circuit board from its upper surface (the first main surface) toward its lower surface (the second main surface). The printed circuit board according to this embodiment is characterized in that a digging depth check terminal 302 is electrically connected to the through hole 303 (the outer conductor formed on its inside wall) as well as signal wirings 301a, 301b which are provided on the different lying levels. In this embodiment, the digging depth of the through hole 303 (the stub length of the through hole 303) is controlled with high precision by detecting that the signal wiring 301a (301b) and the digging depth check terminal 302 which are in the conductive state before the digging of the through hole 303 are electrically isolated when the digging of the through hole 303 reaches the predetermined depth and stopping its digging processing.

In the printed circuit board of this embodiment shown in FIG. 3, the signal wirings 301a, 301b to transmit signals, the conductive layers 305a-305f connected to a power supply or ground, and the pattern of the conductive material which forms the digging depth check terminal 302 and its connection structure follow the signal wirings 101a, 101b, the conductive layers 105a-105f, and the digging depth check terminal 102 in the embodiment 1 except the structure of the digging depth check terminal 302 which contacts with the through hole 303 (the outer conductor). Also, the through hole 303 and a dielectric material 304 to laminate the patterns of the conductive material (to separate the lying layers) are also formed according to the through hole 103 and the dielectric material 104 in the embodiment 1. Therefore, the digging depth check terminal 302 to monitor the digging depth of the through hole 303 is closer to the signal wiring 301b formed on the lying level of the second layer counting from the first main surface than to the signal wiring 301a formed on the first main surface of the printed circuit board. The digging depth check terminal 302 is formed on the lying level of the second layer counting from the lying level of the signal wiring 301b which is close to this and is connected to the through hole 303 (the outer conductor).

The impedance of the transmission route which is formed electrically connecting the signal wirings 301a and 301b by the through hole 303 is matched by digging the part of the through hole 303 which extends and exists from the lying level of the signal wiring 301b toward the second main surface of the printed circuit board from the second main surface. In other words, the part of the through hole 303 which extends and exists from the lying level of the signal wiring 301b toward the second main surface of the printed circuit board is dug and becomes a stub which has an appropriate length for the impedance matching of the transmission route. This length of the stub also will be described as a residual stub length desired for the impedance matching of the transmission route. The distance which separates the digging depth check terminal 302 and the signal wiring 301b close to this in the direction of laminated layers of the printed circuit board is set to be shorter than the desired residual stub length. When the drill reaches the digging depth check terminal 302, the drill intervenes in the direct electrical connection of the digging depth check terminal 302 and the through hole 303. Therefore, the conductive state changes between the digging depth check terminal 302 and the signal wirings 301a, 301b. Also in this embodiment, in the same way as the embodiment 1, the through hole 303 is dug with the drill which has a radius greater than the radius of the through hole 303. Thereby the dug area (the “aperture” discussed in the embodiment 1) of the through hole 303 which extends from the second main surface of the printed circuit board to its first main surface exhibits a caliber greater than the through hole 303 and its inside wall is formed by the dielectric material 304. Further, the digging depth check terminal 302 is exposed from the inside wall of the dug area of the through hole 303 consisting of the dielectric material 304 by the drill reaching the digging depth check terminal 302.

When digging the through hole 303 of the printed circuit board of this embodiment with a non-conductive digging drill (for example, it is provided with an edge consisting of a non-conductive material), when the digging depth of the through hole 303 by this drill reaches the digging depth check terminal 302, the digging depth check terminal 302 and the signal wirings 301a, 302b which were conductive via the through hole 303 are electrically isolated. Thereby the conductive state between the signal wirings 301a, 301b and the through hole 303 conspicuously changes as compared with when the direct electrical connection of the digging depth check terminal 302 and the through hole 303 is cut by the conductive drill. Therefore, when the non-conductive drill is used for the digging of the through hole 303 of the printed circuit board according to this embodiment, the error in detecting that the digging has reached the digging depth check terminal 302 is reduced and it becomes easier to form the stub of the through hole 303 with the desired residual stub length or the length close to this. Namely, in this embodiment owing to the non-conductive drill it becomes possible to dig the through hole 303 with higher precision as compared with the conductive drill.

### Embodiment 3

In this embodiment a form (an inside level form, a pattern) on the lying level of the conductive material film which is applicable to the digging depth check terminals 102, 2102, 2202 which were described in the embodiment 1 and a conductive layer 605b which will be discussed in a embodiment 5 which will be described later is exemplified. In the explanation below this conductive material film will be discussed as a “digging depth check terminal”.

FIG. 4 is an embodiment of the inside level form of the digging depth check terminal. In FIG. 4, for example, the through hole 103 shown in FIG. 1 is shown being cut at the lying level on which the digging depth check terminal 102 is formed. The digging depth check terminal shown in FIG. 4 is configured with a conductive state detection part 405 in form of a ring surrounding a through hole 401 via an insulating space 403 and a pulled out wiring 402 which is electrically connected to the conductive state detection part 405. The through hole 401 is shown as a ring of the outer conductor formed as a film on its inside wall, and a white area other than the area surrounded by the ring of the outer conductor (for example, the insulating space 403) is an insulating area consisting of a material such as the dielectric material 104 shown in FIG. 1. The pulled out wiring 402 is provided to easily monitor the conductive state between the through hole 401 and the conductive state detection part 405, and, for example, is electrically connected to the conductive material film (the terminal, etc.) formed on the first main surface or the second main surface of the printed circuit board shown in FIG. 1 via a through hole, etc. not shown in FIG. 4.

The conductive state detection part 405 shown in FIG. 4 is characterized in that its inside diameter 404 is smaller than the diameter of the drill which digs the through hole 401. By this characteristic, when the digging drill reaches the conductive state detection part 405 the digging depth of the through hole 401 is monitored with high precision because the through hole 401 and the conductive state detection part 405 are made to have continuity via the digging drill. In this embodiment, a conductor in the form of ring is shown as the conductive state detection part 405, but as long as the conductive state between the conductive state detection part 405 and the signal wiring changes when the digging depth of the through hole 401 reaches the desired residual stub length, the inside level form of the conductive state detection part 405 is not limited to the ring form. Also, it is acceptable that the center of the ring of the conductive state detection part 405 shifts from the center of the through hole 401 as far as the similar condition is satisfied.

In this embodiment it has been shown the structure of the digging depth check terminal in which the conductive state with the signal wiring (the through hole 401 which has continuity to this) changes from the isolation to the continuity by the digging of the through hole 401. However, the conductive state detection part 405 and the pulled out wiring 402 described in this embodiment, as long as they are the digging depth check terminals which detect the change of the conductive state such as this, are applied to the structure in which the conductive state changes from the continuity to the isolation or also to the structure in which its resistance value changes when the digging of the through hole reaches the desired digging depth and bring the similar effect.

### Embodiment 4

In this embodiment, a variation is exemplified in which the digging depth check terminal (the conductive state detection part 405 and the pulled out wiring 402) described in the embodiment 3 is provided on each of a plurality of through holes.

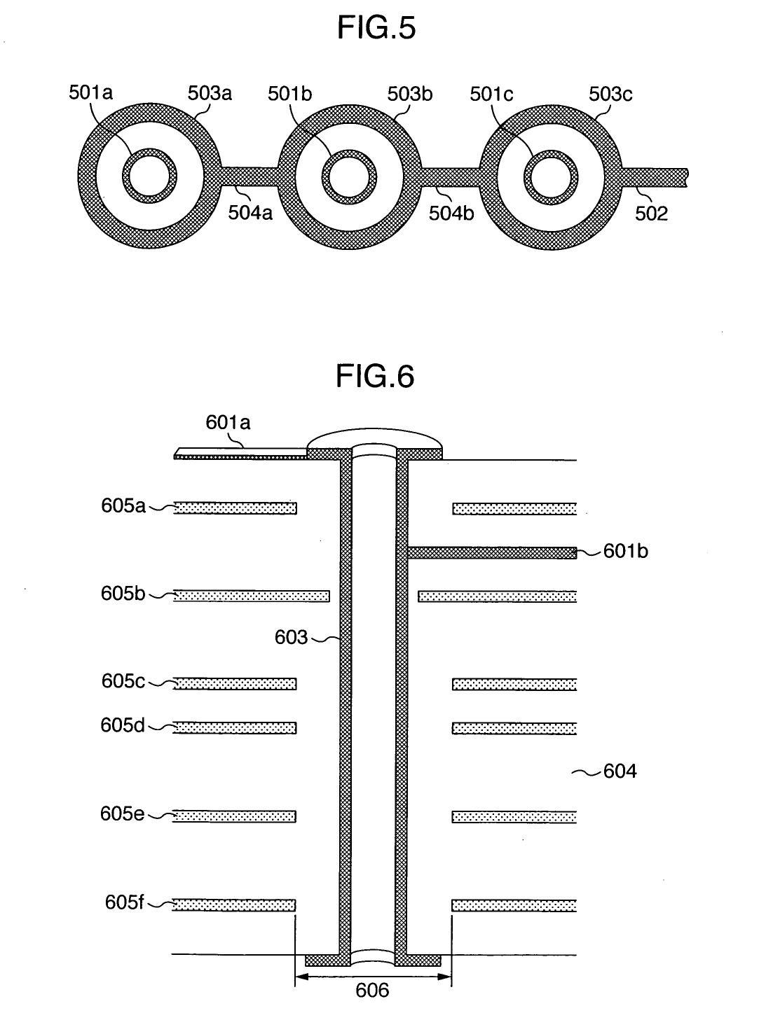

In FIG. 5 an inside level form of the digging depth check terminal provided on each of the plurality of through holes is shown on the lying level of the digging depth check terminal in the same way as FIG. 4. The digging depth check terminal of this embodiment is configured with a plurality of conductive state detection parts 503a-503c in the form of ring which surround each of a plurality of through holes 501a-501c via the insulating space, connection wirings 504a, 504b which electrically cascade the conductive state detection parts 503a-503c within their lying levels, and a pulled out wiring 502 which is electrically connected to the conductive state detection part 503c. Each of the through holes 501a-501c is shown as a ring of the outer conductor formed on its inside wall in the same way as FIG. 4, and the white area other than the area surrounded by each of the rings of the outer conductor (the insulating space, etc.) is the insulating space consisting of the material such as the dielectric material 104 described in the embodiment 1. The pulled out wiring 502 is provided to easily monitor each of the conductive states between the through holes 501a-501c and the conductive state detection parts 503a-503c, and, for example, is electrically connected to the conductive material film (the terminal, etc.) formed on the first main surface or the second main surface of the printed circuit board described in the embodiment 1 via a through hole, etc. not shown in FIG. 5.

In this embodiment it becomes possible to perform the digging processing with high precision by performing the digging processing of the through holes 501a-501c monitoring the conductive state between the through hole which is to be the object of the digging and the digging depth check terminal. As the plurality of conductive state detection parts 503a-503c provided on each of the plurality of through holes 501a-501c have continuity to the pulled out wiring 502, only by monitoring the conductive state of each of the plurality of through holes 501a-501c for the pulled out wiring 502 it is possible to check all of the digging depth of the plurality of through holes 501a-501c. In other words, it becomes unnecessary to apply a probe to each of the conductive state detection parts 503a-503c to measure their conductive states. Moreover, when the outside diameters of the conductive state detection parts 503a-503c is smaller than the diameter of the drill to dig the through holes 501a-501c, it is possible to dig all of the through holes with high precision by performing the digging processing sequentially from the through hole 501awhich has the longest electrical distance from the pulled out wiring 502. According to this embodiment, as compared with the configuration in which one digging depth check terminal is provided for each of the through holes, it becomes possible to reduce the space utilized in the lying level of the digging depth check terminal in the printed circuit board. Therefore, the effect that room for the wiring design on the lying level is increased can also be obtained.

In this embodiment, the structure in which the digging depth check terminals for the three through holes are formed on the same lying level, but the technical idea of this embodiment can be applied to equal to or more than three through holes and it is possible to obtain the effect as described above. Also, even when the plurality of conductive state detection parts are connected in parallel by the connection wiring on these lying levels, the same effect as the cascade of the plurality of conductive state detection parts exemplified in this embodiment can be obtained.

### Embodiment 5

In this embodiment, as a variation of the printed circuit board described in the embodiment 1, structure of the printed circuit board which uses one of the conductive layers 105a-105f formed thereon as the digging depth check terminal 102 without adding the digging depth check terminal 102 is exemplified.

FIG. 6 shows an embodiment of the structure of the printed circuit board in which the conductor connected to the power supply or the ground is used as the digging depth check terminal. The printed circuit board of this embodiment is provided with signal wirings 601a, 601b to transmit signals, conductive layers 605a-605f connected to the power supply or the ground, a dielectric material 604 to laminate the conductive layers, and a through hole 603 to electrically connect the signal wirings 601a, 601b. The signal wirings 601a, 601b and the patterns of the conductive material forming the conductive layers 605a-605f and their connecting structure follow the signal wirings 101a, 101b and the conductive layers 105a-105f in the embodiment 1 except that the insulating area with the through hole 603 on the lying level of one of the conductive layers (605b) is narrower as compared with the others of the conductive layers. Also, the through hole 603 and the dielectric material 604 to laminate the patterns of the conductive material (space the lying layers) are also formed according to the through hole 103 and the dielectric material 104 in the embodiment 1.

Therefore, the impedance of the transmission route which is formed electrically connecting the signal wirings 601a, 601b formed respectively on the different lying layers of the printed circuit board by the through hole 603 is matched by digging the part of the through hole 603 which extends and exists from the lying level of the signal wiring 601b toward the lower surface (the second main surface) of the printed circuit board from the second main surface. In other words, the part of the through hole 603 which extends and exists from the lying level of the signal wiring 601b toward the second main surface of the printed circuit board is dug and becomes the stub which has the length appropriate for the impedance matching of the transmission route.

The printed circuit board shown in FIG. 6 is characterized in that the diameter of the clearance provided in the conductive layers 605a-605f to secure the isolation between the through hole 603 (in FIG. 6 a clearance 606 of a conductive layer 605f is exemplified) is set to be smaller than the diameter of the drill to dig the through hole 603 for the conductive layer 605b which is used as the digging depth check terminal, and is set to be greater than the diameter of the digging drill for the conductive layers 605c-605f which are not used as the digging depth check terminal. Namely, in the step of digging the through hole 603 from the lower surface (the second main surface) of the printed circuit board, by monitoring the conductive state between the conductive layer 605b and the signal wiring 601b and stopping the digging of the through hole 603 at the time point when the conductive state changes, the stub appropriate to match the impedance of the transmission route configured with the signal wirings 601a, 601b electrically connected by the through hole 603 is formed with high precision. In this embodiment also the through hole 603 is dug with the drill which has a radius greater as compared with its radius, thereby the digging processed surface consisting of the dielectric material 604 is formed on the side of the second main surface of the printed circuit board. Moreover, the printed circuit board with the through hole 603 dug to the desired depth exhibits the characteristic that one end of the conductive layer 605b which is used as the digging depth check terminal is exposed from the digging processed surface.

The conductive layer 605b used as the digging depth check terminal is closer to the signal wiring 601b formed on the lying layer of the second layer counting from the upper surface (the first main surface) of the printed circuit board than to the signal wiring 601a formed on the first main surface. The conductor layer 605b used as the digging depth check terminal in FIG. 6 is provided on the lying layer which is located on the side of the second main surface of the printed circuit board on contrary to the signal wiring 601b which is close to this. In this embodiment, the conductive layer 605b formed on the lying layer of the first layer counting from the lying layer on which the signal wiring 601b is formed is used as the digging depth check terminal. However, in accordance with the impedance matching of the transmission route which is formed connecting the signal wirings 601a, 601b by the through hole 603, one of the conductive layers 605c-605f which are laminated on the side of the second main surface of the printed circuit board from the signal wiring 601b may be used as the digging depth check terminal instead of the conductive layer 605b.

The conductive layer 605b used as the digging depth check terminal may be electrically connected to the terminal provided on the first main surface or the second main surface of the printed circuit board through the other through hole not shown in FIG. 6, and this terminal may be used not only for the original use (the reference potential or the application of the power supply potential) of the conductive layer 605b but also for the monitoring of the conductive state between this terminal and the signal wirings 601a, 601b. Further, even if the conductive layer 605b used as the digging depth check terminal is electrically connected to any one of the conductive layers 605a, 605c-605f formed with the same use as this in the printed circuit board, the check (monitoring) of the digging depth of the through hole 603 in this embodiment is not hindered. The technical knowledge described in this paragraph is applied when one of the conductive layers 605c-605f is used as the digging depth check terminal.

According to this embodiment, in the manufacture of the printed circuit board the step to form the digging depth check terminal thereon becomes unnecessary. Namely, the number of the steps to provide a new lying layer in the printed circuit board, and to layout on this lying layer the digging depth check terminal consisting of the conductive state detection part as described in the embodiment 3 and the embodiment 4 and the pulled out wiring to easily monitor the conductive state between the conductive state detection part and the signal wiring (the through hole) is reduced. Thereby it becomes possible to manufacture the printed circuit board with low cost and to dig the through hole provided thereon with high precision.

### Embodiment 6

In this embodiment, as one of the applications of the printed circuit board according to the present invention which has been explained in the embodiments 1 to 5, a transmission device with this circuit mounted will be exemplified.

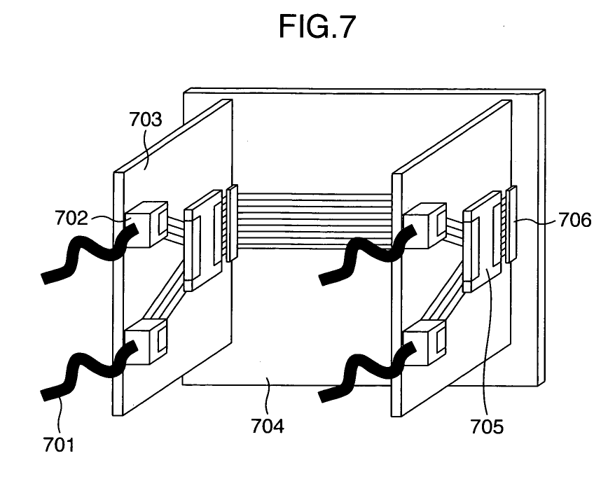

FIG. 7 shows an embodiment of a device which receives and transmits fast speed signals and has the printed circuit board of the present invention mounted. This transmission device switches the transfer route of the transmission signal sent by an optical fiber, and is configured with a plurality of optical modules 702 which convert the transmission signal (the optical signal) to the electrical signal, a plurality of optical fibers 701 which transmit this optical signal, a plurality of switch ICs 705 which determine a transfer route of the transmission signal, a plurality of switch boards 703 which mount the optical module 702 and the switch IC 705, a back board 704 which is to transmit the signal between the plurality of switch boards 703, and a plurality of back-plane connector 706 which electrically connect the switch board 703 and the back board 704. This transmission device is characterized in that the printed circuit board according to the present invention is applied to the above-mentioned switch board 703 or the back board 704.

In this transmission device the optical signal received from the optical fiber 701 is converted to the electrical signal by the optical module 702 to which this optical fiber 701 is connected. Further, this electrical signal is transmitted from the optical module 702 to the switch IC 705 and the transfer route of the electrical signal is determined at the switch IC 705. At this time, according to the determined transfer route the electrical signal is transferred to the other optical module 702 on the switch board 703 or to the optical module 702 which is on the other switch board 703 via the back board 704. The optical module 702 converts the electrical signal which is transferred to this module to the optical signal and transmits this optical signal to the other transmission device by the optical fiber 701 connected to this optical module 702.

By using the printed circuit board according to the present invention to the switch board 703 or the back board 704 of the transmission device such as described above, in the transmission of the electrical signal by these the occurrence of the absence of the transmission data or the malfunction can be restricted and the construction of a signal transmission system with high reliability becomes possible.

Now, the device to which the laminate layers printed circuit according to the present invention is applied is not limited to the above-mentioned transmission device, but, for example, a switch board, a router, a server, a computer and a peripheral device of a computer can be cited.

As described above, the present invention is provided in an information communication system, a computer, and home appliances, and is applied to a printed circuit board or a multi-layer circuit board which is provided with a transmission route of the electrical signal of fast speed or high frequency.

According to the present invention, in the processing technique to dig the stub of the through hole, even when the manufacturing tolerance of the thickness of the printed circuit board or the variation of the depth of the digging by the drill occurs, it is possible to perform the digging processing with high precision and a desired signal wave form improvement effect by the digging processing can be obtained.

The invention may be embodied in other specific forms without departing from the spirit or essential characteristics thereof. The present embodiment is therefore to be considered in all respects as illustrative and not restrictive, the scope of the invention is indicated by the appended claims rather than by the foregoing description, and all changes which come within the meaning and range of equivalency of the claims are therefore intended to be embraced therein.

1. A circuit board provided with a signal wiring to transmit signals, conductive layers which are connected to a power supply or ground, a dielectric material to laminate the signal wiring and the conductive layers, a through hole which extends in a direction of laminated layers of the signal wiring and the conductive layers and is for changing a lying position of the signal wiring in the direction of laminated layers, wherein:
a digging depth check terminal which changes its conductive state with the through hole when the through hole reaches a desired length by being dug is provided.

2. A circuit board according to claim 1, wherein an insulating space is provided between the digging depth check terminal and the through hole, a radius of an area consisting of an outer conductor formed in the through hole and the insulating space surrounding the same is smaller than a digging radius of the through hole.

3. A circuit board according to claim 1, wherein the digging depth check terminals are provided in each of the plurality of through holes respectively, the plurality of digging depth check terminals are electrically connected to each other.

4. A circuit board according to claim 1, wherein the through hole is partly dug from a main surface of the circuit board toward the direction of laminated layers, a digging of the through hole is stopped at the time point when the conductive state between the through hole and the digging depth check terminal has changed.

5. A circuit board provided with a signal wiring to transmit signals, a plurality of conductive layers which are connected to a power supply or ground respectively, a dielectric material to laminate the signal wiring and the plurality of conductive layers alienating them each other, and a through hole which extends in a direction in which the signal wiring and the plurality of conductive layers are laminated and changes a lying position of the signal wiring in the direction of laminated layers, wherein:
between each of the plurality of conductive layers and the through hole a clearance which secures the isolation of each conductive layer and the through hole is provided respectively; and
a form of the clearance provided in one of the plurality of conductive layers is different from a form of the clearance provided in others of the plurality of conductive layers.

6. A circuit board according to claim 5, wherein a diameter of the clearance provided in the one conductive layer is smaller than a diameter of the drill to dig the through hole, and diameters of the clearances provided in the other conductive layers are greater than the diameter of the drill.

7. A circuit board according to claim 5, wherein the through hole is partly dug from a main surface of the circuit board toward the direction of laminated layers, and a digging of the through hole is stopped at the time point when the conductive state between the through hole and the one of the plurality of conductive layers has changed.

8. A circuit board provided with a plurality of conductive layers laminated in a first direction, a dielectric material which spaces the plurality of conductive layers each other, and a through hole which extends and exists in the first direction and electrically connects a pair of the plurality of conductive layers, wherein:
the through hole is terminated with a digging aperture formed by digging the circuit board from one of main surfaces thereof crossing the first direction toward the first direction;
an inside wall of the digging aperture which extends and exists in the first direction consists of the dielectric material; and
one of the plurality of conductive layers other than the pair thereof is exposed from the inside wall of the digging aperture.

9. A transmission device provided with a signal wiring to transmit signals, conductive layers which are connected to a power supply or ground, a dielectric material to laminate the signal wiring and the conductive layers, and a through hole which extends in a direction of laminated layers of the signal wiring and the conductive layers and is for changing a lying position of the signal wiring in the direction of laminated layers, comprising:
a circuit board which is provided with a digging depth check terminal which changes its conductive state with the through hole when the through hole reaches a desired length by being dug; and
a plurality of optical modules which switch a transfer route of a transmission signal sent by an optical fiber, convert the transmission signal to an electrical signal, a plurality of optical fibers which transmit this optical signal, a plurality of switch ICs which determine the transfer route of the transmission signal, a plurality of switch boards which mount the optical module and the circuit board, a back board which is to transmit the signals between the plurality of switch boards, and a plurality of back-plane connectors which electrically connect the switch board and the back board; wherein the through hole is partly dug from a main surface of the circuit board toward the direction of laminated layers, and a digging of the through hole is stopped at the time point when the conductive state between the through hole and the digging depth check terminal has changed.
